(19) United States
(12) Patent Application Publication
(10) Pub. No.: US 2025/0210393 A1
(43) Pub. Date: Jun. 26, 2025

(54) MEMBER FOR SEMICONDUCTOR MANUFACTURING EQUIPMENT

(71) Applicant: NGK INSULATORS, LTD., Nagoya-City (JP)

(72) Inventor: Masaki ISHIKAWA, Handa-City (JP)

(73) Assignee: NGK INSULATORS, LTD., Nagoya-City (JP)

(21) Appl. No.: 18/791,551

(22) Filed: Aug. 1, 2024

Related U.S. Application Data
(63) Continuation of application No. PCT/JP2023/045782, filed on Dec. 20, 2023.

(51) Int. Cl. H01L 21/683; H01J 37/32

(52) U.S. Cl. CPC H01L 21/6833; H01J 37/32715; H01J 2237/2007

(57) ABSTRACT

A member for a semiconductor manufacturing equipment, comprising: a dielectric substrate having an upper surface and an opposed lower surface, a plug placement hole vertically penetrating the substrate, a plug embedded in the plug placement hole and having upper and lower surfaces, a conductive base plate bonded to the lower surface of the substrate via a bonding layer, and a gas supply path passing through the base plate and the bonding layer to supply gas to the plug. The plug is composed of a dielectric material and includes a dense portion, a gas passage that has a relative permittivity lower than that of the dense portion and that penetrates the plug to allow the gas to flow, and a voltage drop promoting portion that has a lower relative permittivity than that of the dense portion and that does not constitute a passage for the gas to flow.

### CROSS REFERENCE TO RELATED APPLICATIONS

The present invention claims the benefit of priority to International Patent Application PCT/JP2023/45782 filed on Dec. 20, 2023 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force. Some members are known that have a function of controlling the temperature of the wafer by flowing gas between the wafer placement surface and the wafer, which is the object to be adsorbed.

An example of a known member for semiconductor manufacturing equipment includes a dielectric substrate having an upper surface on which a wafer is to be placed, a gas passage portion that vertically penetrates the dielectric substrate, and a conductive base plate bonded to the lower surface of the dielectric substrate.

In such a member for a semiconductor manufacturing equipment, a large potential difference from the wafer may occur, and discharge (insulation breakdown) may occur between the wafer and the base plate via the gas passage portion. For this reason, various techniques for arranging plugs in a gas passage portion have been studied in order to suppress discharge. Plugs are often composed of porous materials. If there is no plug, for example, when gas molecules are ionized by the application of an RF voltage, the generated electrons are accelerated and collide with other gas molecules, causing a glow discharge and eventually an arc discharge. However, if there is a plug, it suppresses the discharge because the electrons hit the plug before colliding with other gas molecules.

Patent Literature 1 proposes a plug having a gas flow passage section that penetrates in flexion a dense main body portion in the thickness direction. It has also been proposed that at least a portion of the entire length of the gas flow passage section be made porous and insulating.

Patent Literature 2 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the ceramic dielectric substrate has a first main surface and a first hole portion located between the first main surface and the first porous portion; the first porous portion has a porous portion having a plurality of pores, and a first dense portion that is denser than the porous portion; and configured such that when projected onto a plane perpendicular to a first direction from the base plate to the ceramic dielectric substrate, the first dense portion and the first hole portion overlap, but the porous portion and the first hole portion do not overlap.

Patent Literature 3 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the first porous portion has a plurality of sparse portions having a plurality of pores, and a dense portion having a density higher than the density of the sparse portion; each of the plurality of sparse portions extends in a first direction from the base plate toward the ceramic dielectric substrate; the dense portion is located among the plurality of sparse portions; the sparse portion has the holes and a wall portion provided among the holes; and in a second direction substantially perpendicular to the first direction, the minimum dimension of the wall portion is smaller than the minimum dimension of the dense portion.

Patent Literature 4 describes an invention that aims to provide a holding device that can control the temperature of an object with high accuracy while reducing the occurrence of abnormal discharge. Specifically, it describes a holding device comprising a ceramic substrate having a first surface that holds an object and a second surface located on the opposite side of the first surface; a base member disposed on the second surface side of the ceramic substrate, the base member having a third surface located on the opposite side of the ceramic substrate; and a bonding material disposed between the ceramic substrate and the base member; wherein (1) a passage is formed in the ceramic substrate and the base member to allow fluid to communicate between an outflow hole provided on the first surface and an inflow hole provided on the third surface, or (2) a passage is formed in the ceramic substrate to enable fluid to communicate between an outflow hole provided on the first surface and an inflow hole provided on the second surface; wherein the passage is provided with a porous ceramic region and the porous ceramic region comprises a sparse region and a dense region having a lower porosity than the sparse region and disposed closer to the first surface than the sparse region.

Patent Literature 5 discloses a wafer placement table in which an insulating first porous portion disposed within the through hole of the ceramic plate, and an insulating second porous portion fitted into a recess provided on the ceramic plate side of the base plate so as to face the first porous portion are provided. The gas supplied to the gas introduction path passes through the second porous portion and the first porous portion, flows into the space between the wafer placement surface and the wafer, and is used to cool the object. It is described that due to the presence of the first porous portion and the second porous portion, it is possible to suppress the occurrence of electrical discharge (arc discharge) caused by plasma upon processing wafers while ensuring the gas flow rate from the gas introduction passage to the wafer placement surface.

### PRIOR ART

### Patent Literature

[Patent Literature 1] Japanese Patent Application Publication No. 2022-119338
[Patent Literature 2] Japanese Patent Application Publication No. 2022-31333
[Patent Literature 3] Japanese Patent Application Publication No. 2019-165194
[Patent Literature 4] Japanese Patent Application Publication No. 2022-176701
[Patent Literature 5] Japanese Patent Application Publication No. 2020-72262

### SUMMARY OF THE INVENTION

As described above, various techniques have been proposed for semiconductor manufacturing equipment members to improve the structure in the vicinity of a plug disposed in a gas passage portion that vertically penetrates a dielectric substrate in order to suppress the electrical discharge that occurs between the wafer and the base plate. However, it is believed that developing a technique for suppressing discharge using an approach different from these is significant for the development of technology for members for semiconductor manufacturing equipment. In particular, there is still room for improvement in the technology for suppressing the discharge that occurs in the gas passage portion that vertically penetrates a dielectric substrate near the bonding portion between the dielectric substrate and a base plate.

In view of the above circumstances, an object of an embodiment of the present invention is to provide a member for a semiconductor manufacturing equipment that helps suppress discharge generated in the gas passage portion that vertically penetrates the dielectric substrate near the bonding portion between a dielectric substrate and the base plate.

The present inventor has made extensive studies to solve the above problems, and has created the present invention as exemplified below.

### [Aspect 1]

A member for a semiconductor manufacturing equipment, comprising:
a dielectric substrate having an upper surface on which a wafer is to be placed, and a lower surface opposite to the upper surface,
a plug placement hole that vertically penetrates the dielectric substrate,
a plug embedded in the plug placement hole and having an upper surface and a lower surface,
a conductive base plate bonded to the lower surface of the dielectric substrate via a bonding layer, and
a gas supply path that passes through the base plate and the bonding layer to supply gas to the plug;
wherein the plug is composed of a dielectric material; and
wherein the plug comprises:
a dense portion,
a gas passage that has a relative permittivity lower than that of the dense portion and that penetrates the plug to allow the gas to flow, and
a voltage drop promoting portion that has a lower relative permittivity than that of the dense portion and that does not constitute a passage for the gas to flow.

### [Aspect 2]

The member for a semiconductor manufacturing equipment according to aspect 1, wherein the dense portion has a relative permittivity of greater than 7, and the voltage drop promoting portion has a relative permittivity of 7 or less.

### [Aspect 3]

The member for a semiconductor manufacturing equipment according to aspect 1 or 2, wherein the plug placement hole comprises a truncated conical space in which an area of an upper opening is larger than an area of a lower opening, and the plug comprises a truncated conical shape corresponding to the plug placement hole.

### [Aspect 4]

The member for a semiconductor manufacturing equipment according to any one of aspects 1 to 3, wherein at least a portion of the gas passage is porous.

### [Aspect 5]

The member for a semiconductor manufacturing equipment according to any one of aspects 1 to 4, wherein the voltage drop promoting portion is porous.

### [Aspect 6]

A member for a semiconductor manufacturing equipment, comprising:
a dielectric substrate having an upper surface on which a wafer is to be placed, and a lower surface opposite to the upper surface,
a plug placement hole that vertically penetrates the dielectric substrate,
a plug embedded in the plug placement hole and having an upper surface and a lower surface,
a conductive base plate bonded to the lower surface of the dielectric substrate via a bonding layer, and
a gas supply path that passes through the base plate and the bonding layer to supply gas to the plug;
wherein the plug is composed of a dielectric material;
wherein the plug comprises:
a dense portion,
a gas passage that penetrates the plug to allow the gas to flow;
wherein a gas introduction space communicating with the gas supply path and the gas passage is provided between the lower surface of the plug and the bonding layer; and
wherein a dielectric material that allows a flow of the gas is placed in the gas introduction space.

### [Aspect 7]

The member for a semiconductor manufacturing equipment according to aspect 6, wherein the dielectric material that allows the flow of the gas has a relative permittivity of 1 to 11.

### [Aspect 8]

The member for a semiconductor manufacturing equipment according to aspect 6 or 7, wherein the dense portion has a relative permittivity of greater than 7.

### [Aspect 9]

The member for a semiconductor manufacturing equipment according to any one of aspects 6 to 8, wherein a distance in a vertical direction from an inlet of the gas passage through the gas introduction space to an upper surface of the bonding layer is 500 μm or less.

### [Aspect 10]

The member for a semiconductor manufacturing equipment according to any one of aspects 6 to 9, wherein at least a portion of the gas passage is porous.

### [Aspect 11]

The member for a semiconductor manufacturing equipment according to any one of aspects 6 to 10, wherein the gas passage is porous.

### [Aspect 12]

The member for a semiconductor manufacturing equipment according to any one of aspects 6 to 11, wherein the plug placement hole comprises a truncated conical space in which an area of an upper opening is larger than an area of a lower opening, and the plug comprises a truncated conical shape corresponding to the plug placement hole.

According to an embodiment of the present invention, a member for a semiconductor manufacturing equipment is effective in suppressing the discharge generated between a wafer and a base plate, in particular, the discharge that occurs in a gas passage portion that vertically penetrates the dielectric substrate near the bonding portion between the dielectric substrate and the base plate.

### BRIEF DESCRIPTION OF THE DRAWINGS

FIG. 1 is a schematic vertical cross-sectional view of a member for a semiconductor manufacturing equipment according to an embodiment of the present invention.

FIG. 2 is a partially enlarged view of FIG. 1.

FIG. 3 is a schematic plan view of a dielectric substrate according to one embodiment.

FIG. 4 schematically shows a mechanism in which the potential decreases from the wafer toward the bonding layer in a member for a semiconductor manufacturing equipment.

FIG. 5 is a schematic vertical cross-sectional view of a member for a semiconductor manufacturing equipment according to another embodiment of the present invention.

FIGS. 6A-6C are manufacturing process diagrams of a member for a semiconductor manufacturing equipment according to an embodiment of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal plane with a base plate facing downward, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### <1. Configuration of Member for Semiconductor Manufacturing Equipment>

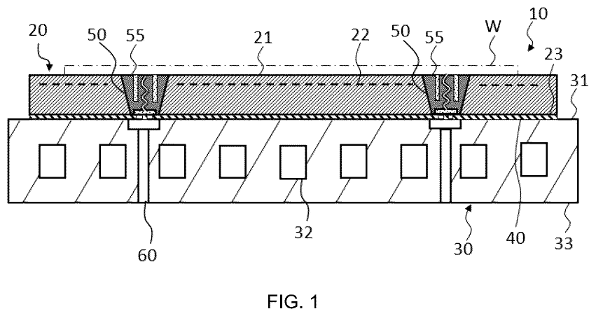

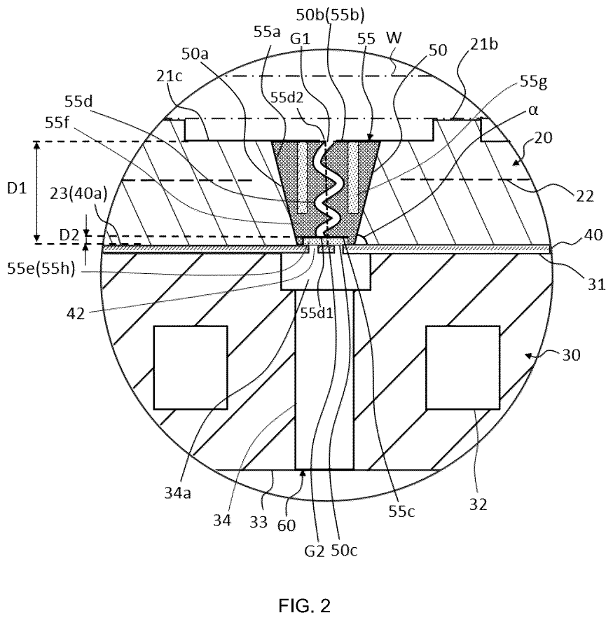

Referring to FIGS. 1 and 2, a member 10 for a semiconductor manufacturing equipment according to an embodiment of the present invention comprises:
a dielectric substrate 20 having an upper surface 21 on which a wafer is to be placed and a lower surface 23 opposite to the upper surface 21;
a plug placement hole 50 that vertically penetrates the dielectric substrate 20;
a plug 55 embedded in the plug placement hole 50 and having an upper surface 55b and a lower surface 55c;
a conductive base plate 30 bonded to the lower surface 23 of the dielectric substrate 20 via a bonding layer 40; and
a gas supply path 60 that passes through the base plate 30 and the bonding layer 40 to supply gas to the plug 55.

The dielectric substrate 20 can be, for example, a circular plate (for example, 300 to 400 mm in diameter) made of ceramics such as alumina sintered body or aluminum nitride sintered body. Although the thickness of the dielectric substrate 20 is not limited, from the viewpoint of increasing the fixing strength of the plug 55, it is preferable that the thickness from an upper opening 50b to a lower opening 50c be 1 mm or more. Further, from the viewpoint of reducing heat transfer of the dielectric substrate 20 and reducing manufacturing costs, the thickness is preferably 5 mm or less, more preferably 3 mm or less, and even more preferably 2 mm or less. Therefore, the thickness from the upper opening 50b to the lower opening 50c is preferably 1 to 5 mm, more preferably 1 to 3 mm, and even more preferably 1 to 2 mm, for example. Here, the thickness from the upper opening 50b to the lower opening 50c means the distance D1 from the center of gravity G1 of the upper opening 50b to the center of gravity G2 of the lower opening 50c. The height of the upper opening 50b is equal to the height of the reference surface 21c of the upper surface 21 of the dielectric substrate 20. The height of the lower opening 50c is equal to the height of the lower surface 23 of the dielectric substrate 20.

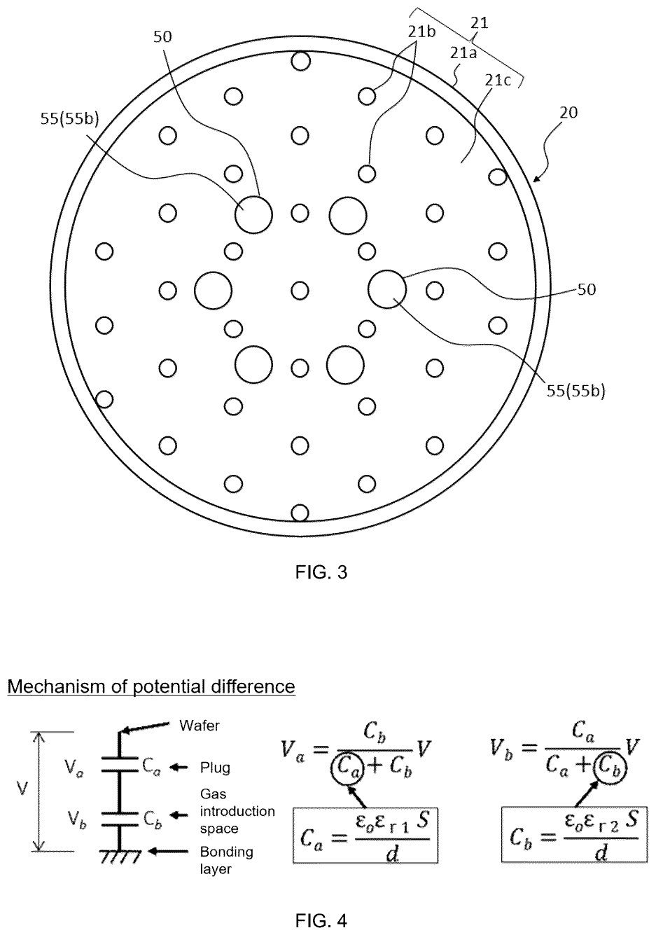

The upper surface 21 of the dielectric substrate 20 has a wafer placement surface on which the wafer W is to be placed. An electrode 22 is provided inside the dielectric substrate 20. As shown in FIG. 3, on the upper surface 21 of the dielectric substrate 20, an annular seal band 21a is formed along the outer edge, and a plurality of small protrusions 21b are formed on the entire surface inside the seal band 21a. Although the shape of the small protrusion 21b is not limited, it can be, for example, a cylinder, a prism, or the like. It is preferable that the seal band 21a and the small protrusions 21b have the same height, and the height is, for example, 5 to 100 μm, and typically 10 to 30 μm. The electrode 22 is a planar electrode used as an electrostatic electrode, and is connected to an external DC power source via a power supply member (not shown). A low-pass filter may be placed in the middle of the power supply member. The power supply member is electrically insulated from the bonding layer 40 and the base plate 30. When a DC voltage is applied to this electrode 22, the wafer W is adsorbed and fixed to the wafer placement surface (specifically, the upper surface of the seal band 21a and the upper surface of the small protrusion 21b) by electrostatic attraction force, and when the application of the DC voltage is released, the adsorption and fixation of the wafer W to the wafer placement surface is released. In addition, the portion of the upper surface 21 of the dielectric substrate 20 where the seal band 21a and the small projections 21b are not provided is referred to as the reference surface 21c.

As the electrode 22, a heater electrode (resistance heating element) may be incorporated instead of or in addition to the electrostatic electrode. In that case, a heater power source is connected to the heater electrode. One layer of electrode may be provided inside the dielectric substrate 20, or two or more layers which are spaced apart from each other may be provided inside the dielectric substrate 20.

The conductive base plate 30 is a circular plate (having a diameter equal to or larger than that of the dielectric substrate 20) with good electrical conductivity and thermal conductivity. Inside the base plate 30, a refrigerant passage 32 through which refrigerant circulates may be formed. The refrigerant flowing through the refrigerant passage 32 is preferably liquid and preferably electrically insulating. Examples of the electrically insulating liquid include fluorine-based inert liquids. The refrigerant passage 32 can be formed, for example, in a single stroke across the entire base plate 30 from one end (inlet) to the other end (outlet) in a plan view. A supply port and a recovery port of an external refrigerant device (not shown) are connected to the one end and the other end of the refrigerant passage 32, respectively. The refrigerant supplied from the supply port of the external refrigerant device to the one end of the refrigerant passage 32 passes through the refrigerant passage 32 and then returns from the other end of the refrigerant passage 32 to a recovery port of the external refrigerant device, and after the temperature has been adjusted, the refrigerant is again supplied to the one end of the refrigerant passage 32 from the supply port. The base plate 30 is connected to a radio frequency (RF) power source and can also be used as an RF electrode.

Examples of the material of the base plate 30 include metal materials and composite materials of metal and ceramics. Examples of the metal material include Al, Ti, Mo, W, and alloys thereof. Examples of composite materials of metal and ceramics include metal matrix composites (MMC) and ceramic matrix composites (CMC). Specific examples of such composite materials include materials containing Si, SiC, and Ti (also referred to as SiSiCTi), materials in which porous SiC is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a coefficient of thermal expansion close to that of the material for the dielectric substrate 20. For example, when the dielectric substrate 20 is made of alumina, the base plate is preferably made of SiSiCTi or AlSiC.

As shown in FIG. 2, the upper surface 31 of the base plate 30 is bonded to the lower surface 23 of the dielectric substrate 20 via a bonding layer 40. The bonding layer 40 is formed by, for example, TCB (thermal compression bonding). TCB is a known method in which a metal bonding material is sandwiched between two members to be bonded, and the two members are pressure bonded while being heated to a temperature below the solidus temperature of the metal bonding material. The bonding layer 40 can be composed of a metal bonding layer using, for example, an Al—Mg-based bonding material or an Al—Si—Mg-based bonding material. The bonding layer 40 may be a layer formed of solder or a metal brazing material. Furthermore, the bonding layer 40 may be composed of a resin adhesive layer instead of the metal bonding layer. Examples of the material for the resin adhesive layer include silicone resin-based adhesives, epoxy resin-based adhesives, and acrylic resin-based adhesives. In order to improve the uniformity of the thickness of the resin adhesive layer, a spacer (not shown) may be placed between the upper surface 31 of the base plate 30 and the lower surface 23 of the dielectric substrate 20.

The bonding layer 40 has a through hole 42. The through hole 42 is provided at a position facing a large diameter portion 34a of a gas hole 34. The through hole 42 may be provided coaxially with the large diameter portion 34a, and the diameter of the through hole 42 may be made to match the diameter of the large diameter portion 34a. As used herein, “match” includes not only a complete match but also a substantially match (for example, within a tolerance range) (the same applies hereinafter). In the present embodiment, the gas hole 34 and the through hole 42 correspond to the gas supply path 60 that passes through the base plate 30 and the bonding layer 40 to supply gas to the plug 55. A plurality of through holes 42 may be provided for one plug 55, and in this case, it is preferable that the plurality of through holes 42 be provided point-symmetrically with respect to the central axis of the plug 55 extending in the vertical direction. Providing a plurality of through holes 42 can reduce the size of each through hole 42 rather than using one large through hole 42, thereby reducing the risk of electrical discharge. Further, by providing a plurality of through holes 42, a necessary gas flow rate can be ensured.

The plug placement hole 50 is a hole that vertically penetrates the dielectric substrate 20, as shown in FIGS. 1 and 2. The plug placement hole 50 is a gas passage from the lower surface 23 of the dielectric substrate 20 to the reference surface 21c of the upper surface 21. The opening diameter (if the cross section of the plug placement hole is not circular, it means the equivalent circle diameter.) of the plug placement hole 50 in the horizontal direction is not limited, but may be within the range of 1 to 5 mm, typically within the range of 3 to 4 mm, at any height position. The diameter of the plug placement hole 50 may be constant from the lower surface 23 to the upper surface 21 of the dielectric substrate 20, or may vary. In one embodiment, the diameter of the plug placement hole 50 may decrease from top to bottom, and it may have a tapered inner peripheral surface 50a in which the area of the upper opening 50b is larger than the area of the lower opening 50c. If the plug placement hole 50 has such a tapered inner peripheral surface 50a, when embedding the plug 55 into the plug placement hole 50, the plug 55 can easily stop at a predetermined height position of the plug placement hole 50. Therefore, it is possible to obtain an effect that the plug can be embedded in the plug placement hole with high positioning accuracy. Further, while the plug becomes difficult to come out downward, it becomes relatively easy to come out upward, so that the effect of making it easy to replace the plug can be obtained. Furthermore, since the creepage distance becomes longer, an effect of suppressing discharge can also be obtained. The plug placement hole 50 can have, for example, a truncated conical or truncated pyramid space.

The inclination angle α of the inner peripheral surface 50a of the plug placement hole 50 with respect to the lower opening 50c is preferably 70° or more, and more preferably 75° or more, from the viewpoint of increasing the fixing strength of the plug 55, and from the viewpoint of suppressing the volume of the plug 55 from becoming excessively large and securing space for arranging the electrode around it. In addition, it is preferable that the inclination angle α be 87° or less, and more preferable that it is 85° or less, from the viewpoint of improving the positioning accuracy in the height direction of the plug when press-fitting the plug 55 downward into the plug placement hole 50, from the viewpoint of making it easy to replace the plug 55, and from the viewpoint of increasing the creepage distance to prevent discharge. Therefore, the inclination angle α is preferably, for example, 70° to 87°, and more preferably 75° to 85°.

As shown in FIG. 3, in the member 10 for a semiconductor manufacturing equipment according to the present embodiment, a plurality of (six in this case) plug placement holes 50 are provided. A plug 55 is embedded in the plug placement hole 50. The plug 55 has a gas passage 55d that penetrates the inside of the plug 55. In one embodiment, the gas passage 55d has one opening on the lower surface 55c of the plug 55 and the other opening on the upper surface 55b, and penetrates the inside of the plug 55 in the vertical direction. In another embodiment, the gas passage 55d has one opening in the lower surface 55c of the plug 55 and the other opening in the outer peripheral surface 55a, and penetrates the inside of the plug 55. The outer peripheral surface 55a of the plug 55 and the inner peripheral surface 50a of the plug placement hole 50 may be bonded together with an adhesive, but it is preferable that they fit directly together without using an adhesive. If the two are directly fitted, no gap will be created between the plug 55 and the plug placement hole 50 caused by deterioration due to corrosion or erosion of the adhesive. Therefore, there is an advantage that discharge and falling off of the plug 55 due to deterioration of the adhesive can be suppressed.

As shown in FIGS. 1 and 2, when observing a longitudinal cross section obtained by cutting the dielectric substrate 20 in the thickness direction, it is preferable that the inner peripheral surface 50a of the plug placement hole 50 be in contact with the outer peripheral surface 55a of the plug 55 in a parallel positional relationship, from the viewpoint of improving the fixing strength of the plug 55. In other words, the outer peripheral surface 55a of the plug 55 has the same inclination angle as the inner peripheral surface 50a of the plug placement hole 50. Therefore, in a preferred embodiment, the plug has an outer shape that is the same as the plug placement hole (for example, a truncated cone or a truncated pyramid). Thereby, the area in which the inner peripheral surface 50a of the plug placement hole 50 contacts the outer peripheral surface 55a of the plug 55 can be increased, and high fixing strength can be obtained.

An example of a direct fitting method is a method of embedding the plug 55 by press-fitting it into the plug placement hole 50. In this case, in order to obtain the desired fixation strength, it is preferable that the cross-sectional diameter in the horizontal direction at any height position of the plug 55 before press-fitting is made slightly larger (for example, by about 5 to 20 μm in equivalent circle diameter) than the horizontal cross-sectional diameter of the plug placement hole 50 located at the same height position. Further, as a direct fitting method, there is also a method in which a male threaded portion provided on the outer peripheral surface 55a of the plug 55 is screwed into a female threaded portion provided on the inner peripheral surface 50a of the plug placement hole 50. Furthermore, the plug 55 may be formed by injecting a paste-like ceramic mixture that is a precursor of the plug 55 into the plug placement hole 50 of the dielectric substrate 20 and firing it.

The plug 55 may be composed of a dielectric material. Specifically, electrically insulating ceramics may be used as the material constituting the plug 55, and for example, it may contain one or more selected from aluminum oxide and aluminum nitride. It may also be composed of only one or two selected from aluminum oxide and aluminum nitride, excluding impurities. Further, in order to maintain the fixing strength of the plug 55, it is preferable that the difference in thermal expansion coefficient between the plug 55 and the dielectric substrate 20 is small. Therefore, it is preferable that the material constituting the plug 55 and the material constituting the dielectric substrate 20 both contain one or more selected from aluminum oxide and aluminum nitride, and it is more preferable that the material compositions are the same.

The height position of the upper surface 55b of the plug 55 is not limited. Therefore, it may be set at the same height as the reference surface 21c of the dielectric substrate 20, or may be set at a different height. However, it is preferable that the height position of the upper surface 55b of the plug 55 be the same as the reference surface 21c. When the upper surface 55b of the plug 55 is lower than the reference surface 21c, it is preferable to arrange it at a lower position within a range of 0.5 mm or less (preferably 0.2 mm or less, and more preferably 0.1 mm or less) in order to suppress the occurrence of discharge. When the upper surface of the plug 55 is made higher than the reference surface 21c, there is no particular restriction as long as it is made lower than the upper surface of the small protrusion 21b and the outflow of the gas from the plug 55 is not inhibited.

There is no particular restriction on the height position of the lower surface 55c of the plug 55. Therefore, it may be at the same height as the lower surface 23 of the dielectric substrate 20, or may be at a different height. For example, the lower surface 55c of the plug 55 may protrude below the lower surface 23 of the dielectric substrate 20, or the lower surface 55c of the plug 55 may be located above the lower surface 23 of the dielectric substrate 20. However, for gas to be easily introduced from the lower surface 55c of the plug 55, it is preferable to provide a gas introduction space 55e communicating with the gas supply path 60 between the lower surface 55c of the plug 55 and the bonding layer 40. The gas introduction space 55e can be formed, for example, by a recess provided in the lower surface 55c of the plug 55.

From the viewpoint of ensuring gas permeability, the vertical distance D2 from the inlet 55d1 of the gas passage 55d to the upper surface 40a of the bonding layer 40 through the gas introduction space 55e is preferably 0.01 mm or more, and more preferably 0.05 mm or more. On the other hand, from the viewpoint of suppressing discharge, the distance D2 is preferably 0.5 mm or less, more preferably 0.1 mm or less, and even more preferably 0.05 mm or less. Therefore, the distance D2 is, for example, preferably 0.01 to 0.5 mm, more preferably 0.01 to 0.1 mm, and even more preferably 0.01 to 0.05 mm.

FIG. 4 schematically shows a mechanism in which the potential decreases from the wafer W toward the bonding layer 40 in the member 10 for a semiconductor manufacturing equipment according to the present embodiment, where the plug 55 and the gas introduction space 55e are regarded as capacitors with capacitances Ca and Cb, respectively. When the gas introduction space 55e is provided between the lower surface 55c of the plug 55 and the bonding layer 40, the Vb in the gas introduction space 55e is large, so that discharge is likely to occur in this vicinity. Since V=Va+Vb, by increasing Va in the plug 55, Vb can be decreased. In order to increase Va, Ca may be decreased, but this can be achieved by decreasing the relative permittivity εᵣ₁ of the plug 55.

Accordingly, in an embodiment of the present invention, the plug 55 comprises a dense portion 55f, a gas passage 55d that has a relative permittivity lower than that of the dense portion 55f and that penetrates the plug 55 to allow the gas to flow, and a voltage drop promoting portion 55g that has a lower relative permittivity than that of the dense portion 55f and that does not constitute a passage for the gas to flow. By providing the plug 55 with the voltage drop promoting portion 55g separate from the gas passage 55d, the overall relative permittivity of the plug 55 can be further reduced.

The dense portion 55f refers to a portion of the plug 55 that has a porosity of 5% or less. Therefore, it is a prerequisite that the voltage drop promoting portion 55g be a portion with a porosity exceeding 5%. The partial porosity of the plug 55 is measured by the following method. First, the plug 55 is cut so that a cross section passing through the central axis extending in the vertical direction of the plug 55 is exposed. Next, the portion of the cross section to be measured for porosity is observed using a scanning electron microscope (SEM) at a magnification of 3000 times in approximately 2200 μm², and the area ratio of pores confirmed in the portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pores to the total area (the total area of the solid portions and the pore portions) is determined, and this is taken as the porosity of this portion to be measured.

The voltage drop promoting portion 55g may be provided at one location on the plug 55, or may be provided at two or more locations. Further, the voltage drop promoting portion 55g may be provided only inside the plug 55, or may have a portion exposed to the upper surface 55b and/or lower surface 55c of the plug 55. Moreover, since the outer peripheral surface 55a of the plug 55 is preferably dense as described later, it is preferable that the voltage drop promoting portion 55g do not have a portion exposed to the outer peripheral surface 55a.

From the viewpoint of increasing the voltage drop in the plug 55, the upper limit of the relative permittivity of the voltage drop promoting portion 55g is preferably 7 or less, more preferably 5 or less. In addition, from the viewpoint of suppressing the decrease in the strength and toughness of the plug and the occurrence of cracks and chipping, the lower limit of the relative permittivity of the voltage drop promoting portion 55g is preferably 1 or more, more preferably 2 or more, and even more preferably 3 or more. Therefore, the relative permittivity of the voltage drop promoting portion 55g is preferably 1 to 7, more preferably 2 to 5, and even more preferably 3 to 5, for example. The relative permittivity of the voltage drop promoting portion 55g can be adjusted by the material constituting the voltage drop promoting portion 55g, as well as the density and the porosity. For example, by increasing the porosity or decreasing the density of the voltage drop promoting portion 55g, the relative permittivity can be decreased, and by lowering the porosity or increasing the density of the voltage drop promoting portion 55g, the relative permittivity can be increased.

On the other hand, from the viewpoint of suppressing insulation breakdown between the electrode and the ceramic, the lower limit of the relative permittivity of the dense portion 55f is preferably larger than 7, and even more preferably 8 or more. In addition, from the viewpoint of dropping the voltage, the upper limit of the relative permittivity of the dense portion 55f is preferably 11 or less. Therefore, the relative permittivity of the dense portion 55f is preferably greater than 7 and less than or equal to 11, and more preferably 8 to 11, for example.

As used herein, the relative permittivity of the dense portion 55f and the voltage drop promoting portion 55g in the plug 55 are both measured using an impedance analyzer (for example, Impedance Analyzer 4291A manufactured by Keysight Technologies) in an environment of normal temperature and normal humidity.

From the viewpoint of increasing the voltage drop in the plug 55, it is preferable that the lower limit of the volume occupied by the voltage drop promoting portion 55g in the plug be 10% or more. Furthermore, if the density is lowered by increasing the porosity for lowering the relative permittivity, lowering the density too much may reduce the strength and toughness of the plug, making it more likely to cause cracks and chipping. Therefore, the upper limit of the volume occupied by the voltage drop promoting portion 55g in the plug is preferably 50% or less, more preferably 30% or less, and even more preferably 20% or less. Therefore, the volume occupied by the voltage drop promoting portion 55g in the plug is preferably 10 to 50%, more preferably 10 to 30%, and even more preferably 10 to 20%.

Preferably, the plug 55 has a dense outer peripheral surface 55a. If the plug 55 has a dense outer peripheral surface 55a, when the plug 55 is directly fitted to the inner peripheral surface 50a of the plug placement hole 50, a sufficient frictional force acts, thereby increasing the fixing strength of the plug 55. The fact that the outer peripheral surface 55a is dense means that the porosity of the outer peripheral surface 55a is 5% or less. The porosity of the outer peripheral surface 55a is preferably 1% or less, more preferably 0.5% or less.

The porosity of the outer peripheral surface 55a is measured by the following method. The plug 55 is cut such that a cross section perpendicular to the outer peripheral surface 55a of the plug 55 is exposed. Next, a 100 μm thick portion of the cross section from the outer peripheral surface 55a is observed using a scanning electron microscope (SEM) at a magnification of 3000 times in approximately 2200 μm², and the area ratio of pores confirmed in the relevant thickness portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pore portions to the total area (total area of the solid portions and the pore portions) is determined. The same measurements are performed at five locations on the same plug 55, and the average value of the measurements at five locations is taken as the porosity of the outer peripheral surface 55a of the plug 55.

Further, when the outer peripheral surface 55a of the plug 55 and the inner peripheral surface 50a of the plug placement hole 50 are directly fitted, it is preferable that the inner peripheral surface 50a of the plug placement hole 50 be also dense, from the viewpoint of increasing the fixing strength of the plug 55 due to friction. The fact that the inner peripheral surface 50a is dense means that the porosity of the inner peripheral surface 50a is 5% or less. Therefore, the porosity of the inner peripheral surface 50a is preferably 1% or less, more preferably 0.5% or less.

Since the inner peripheral surface 50a is a part of the dielectric substrate 20, as used herein, the value of the porosity of the dielectric substrate 20 is regarded as the porosity of the inner peripheral surface 50a. The porosity of the dielectric substrate 20 is defined as the open porosity measured according to JIS R1634: 1998, and the measured value is the average value of the open porosity for five samples uniformly taken from the dielectric substrate 20.

The plug 55 has a gas passage 55d penetrating the inside of the plug 55. There are no particular restrictions on the configuration of the gas passage 55d as long as the gas flowing in from the inlet 55d1 provided on the lower surface 55c of the plug 55 can flow through the gas passage 55d provided inside the plug 55, and can flow out from the outlet 55d2 provided on the upper surface 55b of the plug 55. For example, the gas passage 55d may be formed by forming one or more gas passages penetrating in the vertical direction adjacent to the dense portion 55f that does not allow the gas to flow. In this case, the gas flowing in from the lower surface 55c of the plug 55 flows through the gas passage 55d and flows out from the upper surface 55b of the plug 55. The gas passage may be constructed of a straight line, a curved line, or a combination of both, but from the viewpoint of suppressing discharge, it is preferable to have a shape such that the length of the gas passage is longer than the length of the plug 55 in the vertical direction, for example, a curved shape such as a spiral shape or a zigzag shape.

The gas passage 55d may be hollow, but at least a part thereof may be porous as long as gas flow is allowed. When at least a part of the gas passage 55d is porous, the gas flowing in from the lower surface 55c of the plug 55 flows through the gas passage 55d formed by a large number of continuous pores, and flows out from the upper surface 55b of the plug 55. Since three-dimensional (for example, three-dimensional network) continuous pores that exist within the porous material serve as gas passages, the substantial passage length within the gas passage 55d becomes longer compared to the case where the gas passage 55d is hollow, and an effect that electric discharge is less likely to occur can be obtained. It is also possible to further form one or more gas passages within the porous gas passage. Further, in the case where the gas passage 55d is porous, the width of the gas passage 55d may be expanded in a partial region to possess a function of promoting voltage drop in the same manner as the voltage drop promoting portion 55g.

Therefore, the gas passage 55d may be hollow or porous. It is preferable that at least a part of the gas passage 55d is porous. The fact that the gas passage 55d is hollow means that the porosity is 100%. The fact that the gas passage 55d is porous means that the porosity of the gas passage 55d is greater than 5% and less than 100%. When the gas passage 55d is porous, the porosity of the gas passage 55d is preferably large in order to reduce ventilation resistance. Therefore, the porosity of the gas passage 55d is preferably 10% or more, more preferably 40% or more. On the other hand, the porosity of the gas passage 55d is preferably 50% or less in order to lengthen the passage length of the plug 55 and ensure structural strength. Therefore, the porosity of the gas passage 55d is preferably 10% or more and 50% or less, and more preferably 40% or more and 50% or less.

The porosity of the gas passage 55d is measured by mercury porosimetry method (JIS R1655: 2003).

As a method of manufacturing the plug 55 having such a dense portion, a voltage drop promoting portion, and a gas passage, mention may be made to a method of firing a formed body formed using additive manufacturing technology such as a 3D printer, and a method of firing a formed body formed by mold casting using a master mold produced by a lost-wax method, for example. Mold casting is disclosed in, for example, Japanese Patent No. 7144603. In addition, when the voltage drop promoting portion 55g is made of a different material, a method of dividing the plug to change the material of the portion that will become the voltage drop promoting part 55g, followed by co-firing may be used.

Referring to FIG. 4 again, it can be seen that increasing Cb is also effective in reducing Vb for suppressing discharge. This can be achieved by increasing the relative permittivity εr2 of the gas introduction space 55e. Therefore, in one embodiment of the member 10 for a semiconductor manufacturing equipment, a dielectric material 55h that allows the flow of gas, in other words, has air permeability, is arranged in the gas introduction space 55e. In order to enhance the discharge suppression effect, the dielectric material 55h is preferably in contact with both the bonding layer 40 and the plug 55.

The relative permittivity of the dielectric material 55h is preferably 1 or more, and more preferably 3 or more, in order to improve the discharge suppressing effect. On the other hand, the relative permittivity of the dielectric material 55h is preferably not excessively large in order to reduce the voltage drop. Therefore, the relative permittivity of the dielectric material 55h is preferably 11 or less, more preferably 7 or less. The relative permittivity of the dielectric material 55h may be, for example, 1 or more and 11 or less, or 1 or more and 7 or less.

As used herein, the relative permittivity of the dielectric material 55h is measured using an impedance analyzer (for example, 4291A manufactured by Keysight Technologies) in an environment of normal temperature and normal humidity

It is preferable that the porosity of the dielectric material 55h be small from the viewpoint of increasing the relative permittivity. Therefore, the porosity of the dielectric material 55h is preferably 50% or less. On the other hand, the porosity of the dielectric material 55h is preferably large in order to reduce ventilation resistance. Therefore, the porosity of the dielectric material 55h is preferably 10% or more, more preferably 40% or more. Therefore, the porosity of the dielectric material 55h is preferably 10% or more and 50% or less, and more preferably 40% or more and 50% or less, for example.

The porosity of the dielectric material 55h is measured by the following method. First, the dielectric material 55h is cut such that a cross section passing through the central axis extending in the vertical direction of the dielectric material 55h is exposed. Next, the portion of the cross section to be measured for porosity is observed using a scanning electron microscope (SEM) at a magnification of 3000 times in approximately 2200 μm², and the area ratio of pores confirmed in the portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pores to the total area (the total area of the solid portions and the pore portions) is determined, and this is taken as the porosity of this portion to be measured. The same measurements are performed at five locations on the same dielectric material 55h, and the average value of the five locations is taken as the porosity of the dielectric material 55h.

The dielectric material 55h can be made of ceramics, for example. More specifically, it can be made of the same material as described in the description of the plug 55, such as aluminum oxide and/or aluminum nitride, and repeated description will be omitted. In addition, the dielectric material 55h can be made fibrous or porous. When the ceramic is fibrous or porous, the effect of suppressing discharge can be enhanced while suppressing an increase in ventilation resistance.

The porosity of the plug 55 and the dielectric material 55h can be controlled, for example, by adjusting the content of the pore-forming material in the raw material composition before producing by firing the ceramics which they are made of. For example, in order to make the outer peripheral surface of the plug denser, the amount of pore-forming material near the outer peripheral surface may be partially reduced or may not be used. Furthermore, in order to make the inner peripheral surface of the plug placement hole denser, the amount of pore-forming material near the inner peripheral surface may be partially reduced or may not be used.

Referring to FIG. 2, the gas supply path 60 for supplying gas to the gas passage 55d of the plug 55 through the base plate 30 and the bonding layer 40 has, for example, a through hole 42 that vertically penetrates the bonding layer 40 and a gas hole 34 that communicates with the through hole 42 and penetrates the base plate 30 from the upper surface 31 to the lower surface 33. In the present embodiment, the upper surface 31 of the base plate 30 may further comprise a large diameter portion 34 a provided at a position facing the through hole 42. By having the through hole 42 and furthermore the large diameter portion 34a, when placing the plug 55 in the plug placement hole 50, even if there is a manufacturing error in the plug placement hole 50 and/or the plug 55, such a manufacturing error can be absorbed because a space is created that allows the plug 55 to enter.

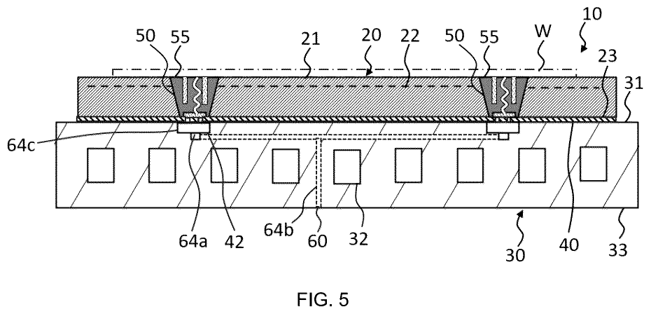

There are no particular restrictions on the configuration of the gas supply path 60. For example, like a member 10 for a semiconductor manufacturing equipment according to another embodiment of the present invention shown in FIG. 5, the base plate 30 may be provided with one or more ring portions 64a having a passage extending concentrically with the base plate 30 in a plan view, one or more gas introduction portions 64b that supply the gas introduced from the lower surface 33 of the base plate 30 to the ring portions 64a, and a distribution portion 64c that distributes the gas from the ring portions 64a to each plug 55. In the present embodiment, the upper end of the distribution portion 64c communicates with the through hole 42 of the bonding layer 40. In FIG. 5, the same components as those in the embodiment shown in FIG. 1 are given the same reference numerals. The number of gas introduction portions 64b may be smaller than the number of distribution portions 64c, and may be one, for example. In this way, the number of gas pipes connected to the base plate 30 can be made smaller than the number of plugs 55. Other auxiliary passages not shown may also be provided.

Further, a lift pin hole may be provided that penetrates the member 10 for a semiconductor manufacturing equipment. The lift pin hole is a hole through which a lift pin for moving the wafer W up and down with respect to the upper surface 21 of the dielectric substrate 20 is inserted. Lift pin holes are provided, for example, at three locations when the wafer W is supported by three lift pins.

### <2. How to Use a Member for Semiconductor Manufacturing Equipment>

Next, a method of using the member 10 for a semiconductor manufacturing equipment configured in this way will be exemplified. First, a wafer W is placed on the upper surface 21 of the dielectric substrate 20 with the member 10 for a semiconductor manufacturing equipment installed in a chamber (not shown). Then, the pressure inside the chamber is reduced with a vacuum pump and adjusted to the desired degree of vacuum, and a voltage is applied to the electrodes 22 of the dielectric substrate 20 to generate electrostatic adsorption force, and the wafer W is adsorbed and fixed to the wafer placement surface (specifically, the upper surface of the seal band 21a or the upper surface of the small protrusion 21b).

Next, the inside of the chamber is set to a reaction gas atmosphere at a predetermined pressure (for example, several tens to several hundreds of Pa), and in this state, a high frequency voltage such as an RF voltage is applied between an upper electrode (not shown) provided on the ceiling of the chamber and the base plate 30 of the member 10 for a semiconductor manufacturing equipment to generate plasma. The surface of the wafer W is processed by the generated plasma. A refrigerant circulates in the refrigerant passage 32 of the base plate 30. Backside gas is introduced into the gas supply path 60 from a gas cylinder (not shown). A thermally conductive gas (for example, He gas) can be used as the backside gas. The backside gas is supplied to the plurality of the plug placement holes 50 through the gas supply path 60, and is supplied and sealed in the space between the back surface of the wafer W and the reference surface 21c of the wafer placement surface. The presence of this backside gas allows efficient heat conduction between the wafer W and the dielectric substrate 20.

Further, by providing the plug 55 in the plug placement hole 50, electric discharge within the plug placement hole 50 can be suppressed. If there is no plug 55, electrons generated as gas molecules are ionized by the application of RF voltage are accelerated and collide with other gas molecules, causing glow discharge and eventually arc discharge. However, when the plug 55 is present, the electrons hit the plug 55 before colliding with the other gas molecules, so that discharge is suppressed.

### <3. Method for Manufacturing a Member for Semiconductor Manufacturing Equipment>

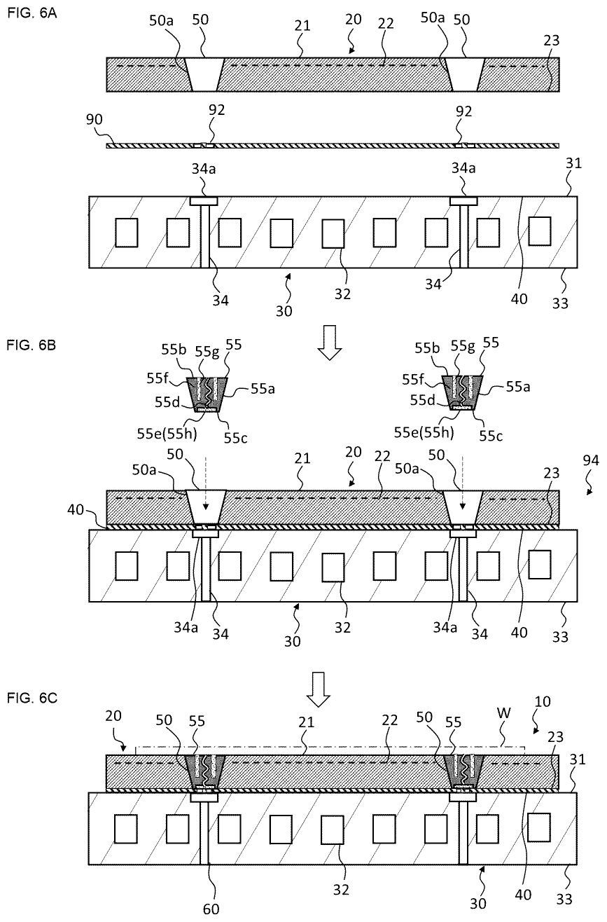

Next, a method for manufacturing the member 10 for a semiconductor manufacturing equipment will be exemplarily described based on FIGS. 6A-6C. FIGS. 6A-6C are manufacturing process diagrams of the member 10 for a semiconductor manufacturing equipment according to an embodiment of the present invention. First, the dielectric substrate 20, the base plate 30, and the metal bonding material 90 are prepared (FIG. 6A).

The dielectric substrate 20 has an electrode 22 therein and a plug placement hole 50. The dielectric substrate 20 can be manufactured by hot press firing a ceramic formed body. The ceramic formed body may be manufactured by laminating a plurality of tape formed bodies, by a mold casting method, or by compacting ceramic powder. Subsequently, the plug placement hole 50 is formed in the dielectric substrate 20. The plug placement hole 50 is formed to vertically penetrate the dielectric substrate 20 while avoiding the electrode 22.

The base plate 30 includes a refrigerant passage 32 and a gas hole 34. The gas hole 34 has a large diameter portion 34a facing the upper surface 31. The base plate 30 including the refrigerant passage 32 can be manufactured, for example, by bonding a plurality of MMC plate members, in which a groove or a hole corresponding to the refrigerant passage 32 is formed, with machining using a method such as TCB (Thermal Compression Bonding). The gas holes 34 can be formed by machining the base plate 30 after the refrigerant passage 32 has been formed.

The metal bonding material 90 includes a through hole 92 at a position facing the large diameter portion 34a of the gas hole 34. The through hole 92 can be formed by machining.

Subsequently, a metal bonding material 90 is sandwiched between the lower surface 23 of the dielectric substrate 20 and the upper surface 31 of the base plate 30 to form a laminate. At this time, it is preferable to laminate them such that the plug placement hole 50 of the dielectric substrate 20, the through hole 92 of the metal bonding material 90, and the gas hole 34 of the base plate 30 are coaxial. Then, the laminate is pressurized and bonded at a temperature no higher than the solidus temperature of the metal bonding material 90 (for example, the temperature 20° C. lower than the solidus temperature or more and no higher than the solidus temperature), and then returned to room temperature (TCB). Thereby, the metal bonding material 90 and the through hole 92 become the bonding layer 40 and the through hole 42, respectively, and a bonded body 94 in which the dielectric substrate 20 and the base plate 30 are bonded by the bonding layer 40 is obtained (FIG. 6B). The metal bonding material 90 preferably has a thickness of approximately 100 μm (for example, 80 to 240 μm).

Next, a truncated conical plug 55 having a dense portion 55f, a gas passage 55d, a voltage drop promoting portion 55g, and a gas introduction space 55e is prepared (FIG. 6B). A dielectric material 55h that allows gas to flow can be placed in the gas introduction space 55e. The height of the plug 55 is the same as the depth of the plug placement hole 50 (that is, the height of the dielectric substrate 20), which is a truncated conical space. Next, the plug 55 is press-fitted into the plug placement hole 50 from the upper opening 50b of the dielectric substrate 20 toward the lower opening 50c. Alternatively, a male threaded portion is formed on the outer peripheral surface 55a of the plug 55, which has been formed in advance by firing or the like, and a female threaded portion is formed on the inner peripheral surface 50a of the plug placement hole 50, and the plug 55 may be installed by screwing and inserting the plug 55 into the plug placement hole 50 so that the male threaded portion of the plug 55 and the female threaded portion of the plug placement hole 50 are screw fitted together. Furthermore, the plug 55 may be formed by injecting a paste-like ceramic mixture that is a precursor of the plug 55 into the plug placement hole 50 of the dielectric substrate 20 and firing it. Thereafter, the member 10 for a semiconductor manufacturing equipment is completed by appropriately going through processes such as adjusting the overall shape (FIG. 6C).

### DESCRIPTION OF REFERENCE NUMERALS

10: Member for semiconductor manufacturing equipment
20: Dielectric substrate
21: Upper surface
21a: Seal band
21b: Small protrusion
21c: Reference surface
22: Electrode
23: Lower surface
30: Base plate
31: Upper surface
32: Refrigerant passage
33: Lower surface
34: Gas hole
34a: Large diameter portion
40: Bonding layer
40a: Upper surface
42: Through hole
50: Plug placement hole
50a: Inner peripheral surface
50b: Upper opening
50c: Lower opening
55: Plug
55a: Outer peripheral surface
55b: Upper surface
55c: Lower surface
55d: Gas passage
55d1: Inlet
55d2: Outlet
55e: Gas introduction space
55f: Dense portion
55g: Voltage drop promoting portion
55h: Dielectric material
60: Gas supply path
64a: Ring portion
64b: Gas introduction portion
64c: Distribution portion
90: Metal bonding material
92: Through hole
94: Bonded body

The invention claimed is:

1. A member for a semiconductor manufacturing equipment, comprising:
a dielectric substrate having an upper surface on which a wafer is to be placed, and a lower surface opposite to the upper surface,
a plug placement hole that vertically penetrates the dielectric substrate,
a plug embedded in the plug placement hole and having an upper surface and a lower surface,
a conductive base plate bonded to the lower surface of the dielectric substrate via a bonding layer, and
a gas supply path that passes through the base plate and the bonding layer to supply gas to the plug;
wherein the plug is composed of a dielectric material; and
wherein the plug comprises:
a dense portion,
a gas passage that has a relative permittivity lower than that of the dense portion and that penetrates the plug to allow the gas to flow, and
a voltage drop promoting portion that has a lower relative permittivity than that of the dense portion and that does not constitute a passage for the gas to flow.

2. The member for a semiconductor manufacturing equipment according to claim 1, wherein the dense portion has a relative permittivity of greater than 7, and the voltage drop promoting portion has a relative permittivity of 7 or less.

3. The member for a semiconductor manufacturing equipment according to claim 1, wherein the plug placement hole comprises a truncated conical space in which an area of an upper opening is larger than an area of a lower opening, and the plug comprises a truncated conical shape corresponding to the plug placement hole.

4. The member for a semiconductor manufacturing equipment according to claim 1, wherein at least a portion of the gas passage is porous.

5. The member for a semiconductor manufacturing equipment according to claim 1, wherein the voltage drop promoting portion is porous.

6. A member for a semiconductor manufacturing equipment, comprising:
a dielectric substrate having an upper surface on which a wafer is to be placed, and a lower surface opposite to the upper surface,
a plug placement hole that vertically penetrates the dielectric substrate,
a plug embedded in the plug placement hole and having an upper surface and a lower surface,
a conductive base plate bonded to the lower surface of the dielectric substrate via a bonding layer, and
a gas supply path that passes through the base plate and the bonding layer to supply gas to the plug;
wherein the plug is composed of a dielectric material;
wherein the plug comprises:
a dense portion,
a gas passage that penetrates the plug to allow the gas to flow;
wherein a gas introduction space communicating with the gas supply path and the gas passage is provided between the lower surface of the plug and the bonding layer; and
wherein a dielectric material that allows a flow of the gas is placed in the gas introduction space.

7. The member for a semiconductor manufacturing equipment according to claim 6, wherein the dielectric material that allows the flow of the gas has a relative permittivity of 1 to 11.

8. The member for a semiconductor manufacturing equipment according to claim 6, wherein the dense portion has a relative permittivity of greater than 7.

9. The member for a semiconductor manufacturing equipment according to claim 6, wherein a distance in a vertical direction from an inlet of the gas passage through the gas introduction space to an upper surface of the bonding layer is 500 μm or less.

10. The member for a semiconductor manufacturing equipment according to claim 6, wherein at least a portion of the gas passage is porous.

11. The member for a semiconductor manufacturing equipment according to claim 6, wherein the gas passage is porous.

12. The member for a semiconductor manufacturing equipment according to claim 6, wherein the plug placement hole comprises a truncated conical space in which an area of an upper opening is larger than an area of a lower opening, and the plug comprises a truncated conical shape corresponding to the plug placement hole.
